(19) United States
(12) Patent Application Publication
(10) Pub. No.: US 2010/0231326 A1
(43) Pub. Date: Sep. 16, 2010

(54) MEMS Compact Switched Capacitor

(75) Inventors: Afshin Ziaei, Vanves (FR); Matthieu Le Baillif, Orsay (FR); William Rebernak, Saint-Denis (FR); Marie-Pierre Dussauby, Saint Leu La Foret (FR); Michel Giraudo, Rueil Malmaison (FR); Gilles Neveu, Sannois (FR)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: THALES, Neuilly-sur-Seine (FR)

(21) Appl. No.: 12/644,597

(22) Filed: Dec. 22, 2009

(30) Foreign Application Priority Data
Dec. 23, 2008 (FR) 08 07411

(51) Int. Cl. H03H 7/00; H01G 7/00

(52) U.S. Cl. 333/174; 361/277

(57) ABSTRACT

A switched capacitor is characterized in that it comprises a series MEMS-type switch, the capacitor to be switched being integrated into the structure of the MEMS switch and being formed by an additional metal layer produced on part of the dielectric layer of the MEMS switch, the capacitance of the switched capacitor being set as a function of the area of the metal layer.

### CROSS-REFERENCE TO RELATED APPLICATIONS

This application claims priority of foreign French patent application no. FR 0807411, filed Dec. 23, 2008, the disclosure of which is hereby incorporated by reference in its entirety.

### BACKGROUND OF THE INVENTION

1. Field of the Invention

The present invention relates to an MEMS compact switched capacitor, the acronym MEMS standing for Micro-Electro-Mechanical Systems. It applies notably to microwave filters.

Switched capacitors allow a better integration of electronic devices, notably filters. For example, switched capacitors make it possible to reproduce the functioning of resistors, and the use of switched capacitors therefore permits integration in a minimum overall size of resistor-based electronic circuits. For example, radiofrequency filters of the RC type can thus be produced in integrated circuits manufactured according to the known techniques of the type with microwave monolithic integrated circuits or MMIC or else specialized integrated circuits or ASIC.

Another use of switched capacitors may be considered for the purpose of obtaining variable capacitances, for example for use in frequency-tunable filters, or else phase shifters, reconfigurable networks or variable resonators. These devices are typically employed in electronic systems of radiofrequency transmitters/receivers: in military or civil radiocommunication stations, radar installations, directional radio links, etc. A variable capacitance may be produced, for example, by means of a bank of switched capacitors connected in parallel.

2. Discussion of the Background

Variable capacitance structures are known in the prior art. It is possible, notably, to produce variable capacitance elements by means of diodes of the Varactor or Varicap type. Diode structures of this type, however, have disadvantages associated with insufficient linearity or with pronounced losses.

It is also possible to produce variable capacitance elements, using capacitors switched by means of electromechanical relays, or else by PIN (Positive Intrinsic Negative) diodes or else by switches of the MEMS type. To produce integrated switched capacitors, this last type of switch is usually preferred on grounds of the performances in microwave ranges; notably, structures based on PIN diodes have the disadvantage of high current consumption. Thus, integrated switched capacitors are produced, for example, by means of the series connection of a MEMS-type switch and of an integrated capacitor.

This structure of switched capacitors is nevertheless relatively bulky and occupies a considerable place in an integrated circuit. To be precise, it is necessary to have an integrated circuit surface for the capacitor, to which it is necessary to add the surface for the switch and the surface necessary for the connecting line between the switch and the capacitor. Moreover, in such a structure, the microwave losses, that is to say the losses associated with mismatching in the region of the interfaces between various elements, result from the losses associated with the interface between the input line and the switch, with the switch itself, with the interface with the line connecting it to the capacitor, with the interface between the line and the capacitor and with the capacitor itself. Finally, the known structures of frequency-tunable filters using switched capacitors with switches of the MEMS type have a limited service life linked to the service life of the MEMS switch.

### SUMMARY OF THE INVENTION

One object of the present invention is to mitigate at least the abovementioned disadvantages by proposing a novel switched capacitor structure in which the capacitor to be switched is directly integrated into the structure of the radiofrequency MEMS switch.

One advantage of the invention is to make it possible to reduce the overall size of the switched capacitor and to reduce the losses and increase the service life.

Another advantage of the invention is linked to the increased lifetime of the switched capacitor, which, by virtue of its original structure, is capable of withstanding a much larger number of operating cycles than a switched capacitor known from the prior art.

The novel integrated structure which is the subject of this invention is matched to the requirements of the system in which it is integrated, for example a frequency-tunable filter.

For this purpose, the subject of the invention is a switched capacitor, characterized in that it comprises a series MEMS-type switch, the MEMS switch comprising a first metal layer, a dielectric material layer, and an actuatable metallic diaphragm having a high state and a low state, the second metal layer being produced on a part of the surface of the dielectric material layer, a line disconnection formed by an absence of metal being implemented on at least the first metal layer and the second metal layer, below the actuatable metallic diaphragm, the capacitor to be switched being formed by the dielectric material layer contained between the mutually confronting surfaces of the first metal layer and of the second metal layer, the diaphragm in the low state being in direct contact with the second metal layer.

In one embodiment of the invention, the switched capacitor described above may be characterized in that the series MEMS switch is of the type of switch with a suspended diaphragm, the diaphragm being located above the line disconnection made at mid-length over the entire width and the entire thickness of at least the first metal layer and the second metal layer, the diaphragm in the low state making ohmic contact between the parts of the second metal layer which are located on either side of the line disconnection.

In one embodiment of the invention, the switched capacitor described above may be characterized in that the series MEMS switch is of the type with a cantilever beam comprising a movable beam having a high state and a low state, the movable beam being located above the second metal layer, the movable beam in the low state making ohmic contact with the second metal layer.

In one embodiment of the invention, the switched capacitor described above may be characterized in that the value of its capacitance is set as a function of the surface of the second metal layer.

In one embodiment of the invention, a plurality of switched capacitors, such as a switched capacitor described above, may be used in a device with switched capacitors.

In one embodiment of the invention, a plurality of switched capacitors, such as a switched capacitor described above, may be used in a variable capacitance device, the switched capacitors having capacitances of specific values and being connected in parallel.

The subject of the present invention is also a frequency-tunable filter comprising a first oscillating circuit, a second oscillating circuit and a coupling device, characterized in that the first oscillating circuit and the second oscillation circuit are tuned respectively by means of two variable-capacitance tuning capacitors, the coupling device being a T-connection of three capacitors, comprising two fixed-capacitance capacitors on the two transverse arms of the T-connection and one variable-capacitance capacitor on the earthed arm of the T-connection, the variable-capacitance capacitors being capacitance devices, such as the variable-capacitance device described above.

In one embodiment of the invention, the frequency-tunable filter described above may be characterized in that the first and second oscillating circuits comprise a T-connection comprising a first coil, a second coil and a third coil, the first and second coils being respectively on the two transverse arms of the T-connection, the third coil being on the earthed arm of the T-connection, a fixed-capacitance capacitor being connected in parallel to the first and second coils.

### BRIEF DESCRIPTION OF THE DRAWINGS

Other characteristics and advantages of the invention may be gathered from a reading of the description, given by way of example and made with reference to the accompanying drawings in which:

FIG. 1 illustrates a top view and a cross-sectional view of an example of a capacitor produced by planar technology known from the prior art;

FIG. 2a illustrates a top view of a structure with a switched capacitor known from the prior art, along with the equivalent electrical diagram;

FIG. 2b illustrates a top view of a variable capacitance produced by means of a connection of a plurality of switched capacitors known from the prior art;

FIG. 3 illustrates a top view and a cross-sectional view of an example of a series MEMS switch structure, with suspended diaphragm, known from the prior art;

FIG. 4a illustrates a top view and cross-sectional view of an example of a switched capacitor according to the invention in the open state, and the equivalent electrical diagram;

FIG. 4b illustrates a cross-sectional view of an example of a switched capacitor according to the invention in the closed state, and the equivalent electrical diagram;

FIG. 5 illustrates a top view and cross-sectional view of various examples of switched capacitor structures according to the invention;

FIG. 6 illustrates a cross-sectional view of another exemplary embodiment of a switched capacitor according to the invention;

FIG. 7 illustrates the electrical diagram of an example of a frequency-tunable filter with constant passband, using switched capacitors according to the invention.

### DESCRIPTION OF THE PREFERRED EMBODIMENTS

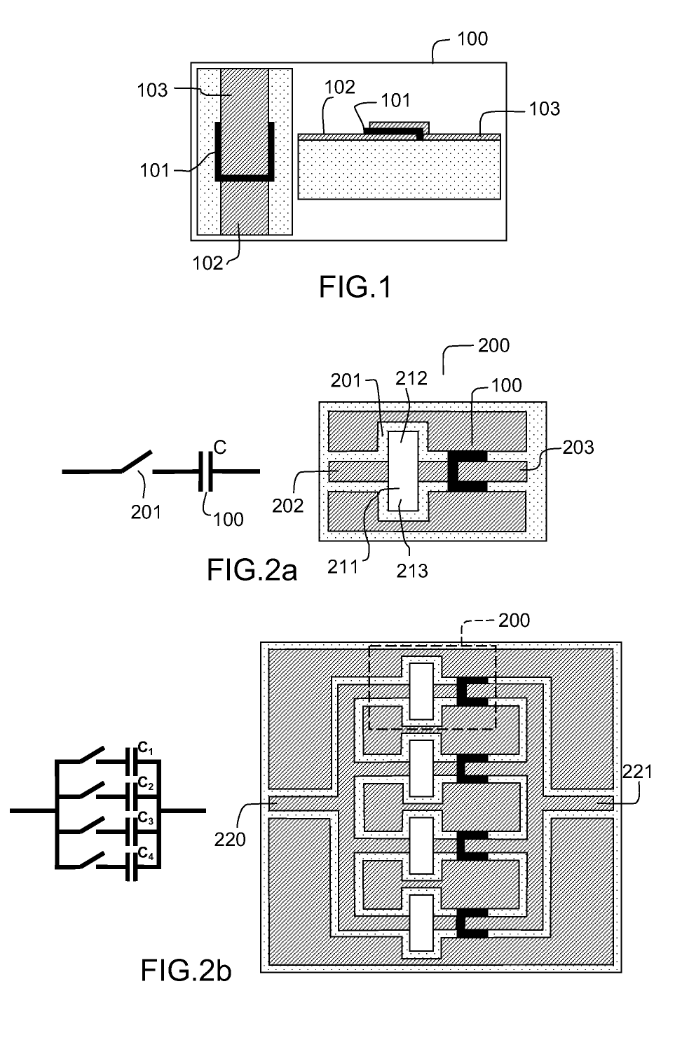

FIG. 1 illustrates a top view and cross-sectional view of an example of a capacitor produced by planar technology known from the prior art. A capacitor 100 comprises a first metallic armament 102, a dielectric layer 101 and a second metallic armament 103. Such a structure may be produced, for example, according to the MIM technique, MIM standing for Metal Insulator Metal, itself known to a person skilled in the art.

There are other types of capacitors produced by planar technology, such as, for example, structures of the interdigitated comb type, having the advantage of being manufactured more easily, but requiring a much larger integration surface. Consequently, it is usually preferable, for the production of switched capacitor structures, to employ MIM capacitors connected in series to switches of the MEMS type.

FIG. 2a has a top view of a switched capacitor structure 200 known from the prior art, and the equivalent electrical diagram corresponding to it.

The switched capacitor structure 200 comprises an input line 202 and an output line 203. A switch of the MEMS type 201 comprises a metallic diaphragm 211 suspended on two pillars 212 and 213 and actuated via two electrodes, not illustrated in the figure. The switch 201 is connected in series to a capacitor of the MIM type 100. The equivalent electrical diagram is that of a switch 201 in series with a capacitor 100.

FIG. 2b has top view of a variable capacitance produced by means of a connection of a plurality of switched capacitors 200. The variable capacitance comprises a line input 220 and a line output 221. A plurality of switched capacitors, each comprising a capacitor 100 and a switch 201, are connected in parallel. The capacitors 100 may have capacitances of equal values or of different values. The opening and closing combinations of the switches 201 make it possible to obtain different values of the equivalent capacitance, the value of which is equal to the sum of the capacitances presented by the capacitors 100, the associated switch 201 of which is closed.

Such a connection occupies a relatively large circuit surface, the surface occupied by a single switched capacitor 200 being equal to the sum of the surfaces occupied by the switch 201, the capacitor 100 and the interconnection line between these two elements. Furthermore, the sources of significant microwave losses are the interfaces between all the elements: the interface between the line input 202 and the switch 201, the interface between the switch 201 and the interconnection line between the switch 201 and the capacitor 100, the interface between the interconnection line and the capacitor 100, the interface between the capacitor 100 and the line output 203, the switch 201 and the capacitor 100 themselves being the source of microwave losses.

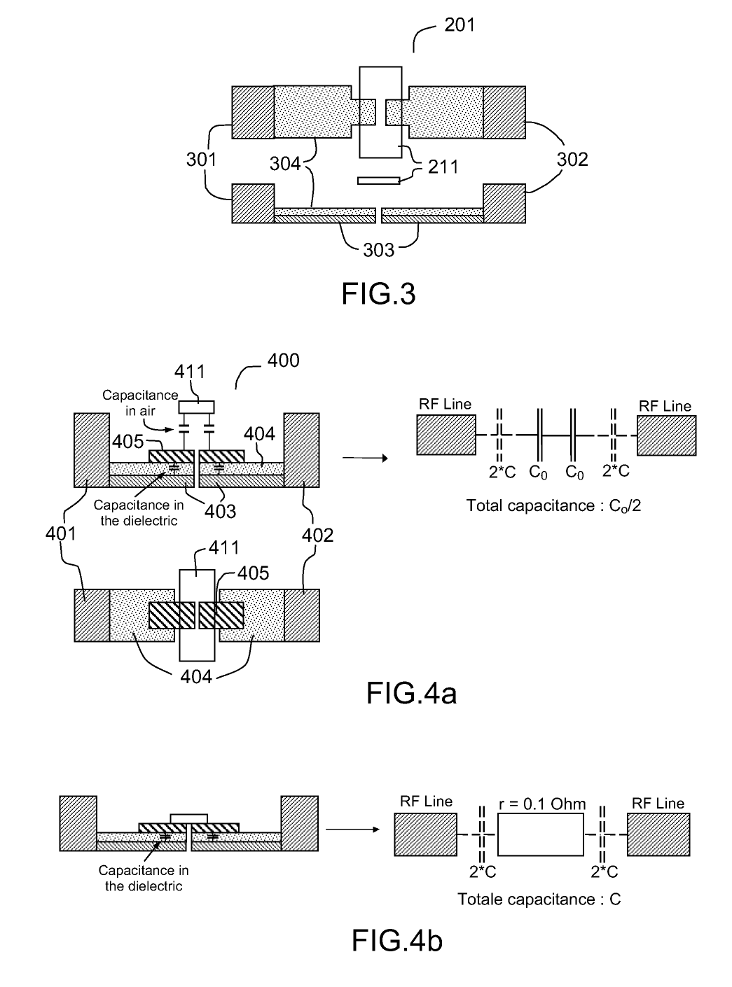

FIG. 3 has a top view and cross-sectional view of an example of a series MEMS switch structure 201, with suspended diaphragm, known from the prior art. The switch comprises an input line 301 and an output line 302. A metal layer 303 is covered with a dielectric layer 304. The two superposed layers connect the input line 301 to the output line 302, an RF line disconnection 306 being formed at mid-length and extending over the entire width and thickness of the metal layer 303 and of the dielectric layer 304, so that no signal can travel between the input line 301 and the output line 302. Advantageously, the RF line disconnection may be formed only over the width and thickness of the metal layer 303, in order to simplify the production process in which the dielectric layer is usually deposited on the entire surface of the semiconductor wafer on which the MEMS switches are implemented. When the switch 201 is in the open position or high position, the diaphragm 211, said to be in the high state, is located at such a distance from the dielectric layer that no HF signal travels between the input line and the output line. When the switch 201 is in the closed position or low position, capacitive coupling occurs between the metallic diaphragm 211, said to be in the low state, and the metal layer 303 via the dielectric layer 304, on either side of the RF line disconnection 306, and the HF signals can travel between the input line 301 and the output line 302.

The whole of the switch 201, including the pillars 212 and 213 and the electrodes for actuating the metallic diaphragm 211, which are not illustrated in this figure, can be implemented on the basis of a single substrate and of successive lithographic operations known per se from the prior art.

FIG. 4a has a top view and cross-sectional view of an example of a switched capacitor 400 according to the invention, in the open state. The switched capacitor 400 comprises an input line 401, an output line 402 and a metallic diaphragm 411 of the suspended diaphragm type, in the high state in this configuration. A first metal layer 403 is covered by a dielectric layer 404. The dielectric layer 404 is covered, on part of its surface, by a second metal layer 405 of area S. The three layers 403, 404, 405 superposed in this way connect the input line 401 to the output line 402, a substantially vertical RF line disconnection 406 being made at mid-length and extending over the entire width and thickness of at least the first metal layer 403 and the second metal layer 405, so that no signal can travel between the input line 401 and the output line 402.

In order of the progress of an RF signal travelling between the input line 401 and the output line 402, there are several capacitances in the various dielectric environments passed: a first capacitance in the dielectric layer 404, between the first metal layer 403 and the second metal layer 405; a second capacitance in the dielectric environment, for example air, between the second metal layer 405 and the metallic diaphragm 411, a third capacitance of equal value, in air, between the metallic diaphragm 411 and the confronting second metal layer 405, beyond the RF line disconnection 406, and a fourth capacitance of a value equal to the first capacitance, beyond the RF line disconnection 406, in the dielectric layer 404, between the second metal layer 405 and the first metal layer 403.

Let 2*C be the value of the first capacitance (equal to the value of the fourth capacitance), and C_{O} be the value of the second capacitance, equal to the value of the third capacitance. The equivalent electrical diagram of the switched capacitor 400 between the input line 401 and the output, line 402 is that of 4 series-connected capacitors having the abovementioned capacitance values. The total capacitance Cₜₒₜₐₗₑ of the structure is given by the following relation:

$$\frac{1}{{C}_{totale}} = \frac{1}{2 ⋆ C} + \frac{1}{{C}_{O}} + \frac{1}{{C}_{O}} + \frac{1}{2 ⋆ C} ; \qquad ( 1 )$$

The switched capacitor 400, then, can be dimensioned so that the capacitance C_{O} is very low in comparison with the capacitance 2*C. Thus, it emerges from the relation (1) that, in first approximation, the total capacitance of the switched capacitor 400 is equal to C_{O}/2. In practice, there are two capacitors of capacitance C_{O} in series which are switched.

FIG. 4b has a cross-sectional view of an example of a switched capacitor 400 according to the invention, in the closed state.

In the closed state, ohmic contact is generated, by the metallic diaphragm 411 in the low state, between the surfaces of the second metal layer 405 on either side of the RF line disconnection. Thus, in the order of the progress of an RF signal travelling between the input line 401 and the output line 402, a first capacitive coupling is implemented in the dielectric layer 404 between the first metal layer 403 and the second metal layer 405, and then a second capacitive coupling in the dielectric layer 404 between the second metal layer 405 and the first metal layer 403. It can thus be noted that it is the metallic diaphragm 411 which performs the function of the connection between the two transmission line parts located on either side of the RF line disconnection. In the same way, the metallic surfaces formed by the second metal layer 405 on either side of the RF line disconnection constitute electrodes to be switched, all or part of each of the metallic surfaces thus formed therefore being located below the metallic diaphragm 411. It can also be noted that the capacitor to be switched is integrated into a structure of the series switch type, the capacitor to be switched notably not being switched to the earth of the device in which it is integrated.

The equivalent electrical diagram of the switched capacitor 400 between the input line 401 and the output line 402 is therefore that of a first capacitor of capacitance 2*C connected in series with a resistance r corresponding to the intrinsic electrical resistance of the metallic diaphragm 411, this resistance typically having a very low value of the order of 0.1 Ohm, and with a second capacitor of capacitance 2*C. The total capacitance Cₜₒₜₐₗₑ of the structure in the closed state is therefore equal to C.

The second metal layer 405 can easily be produced by the lithographic techniques known from the prior art; the production of a switched capacitor 400 according to the invention constitutes merely an additional metallization step with respect to the production of a switch of the MEMS type 201, known per se from the prior art.

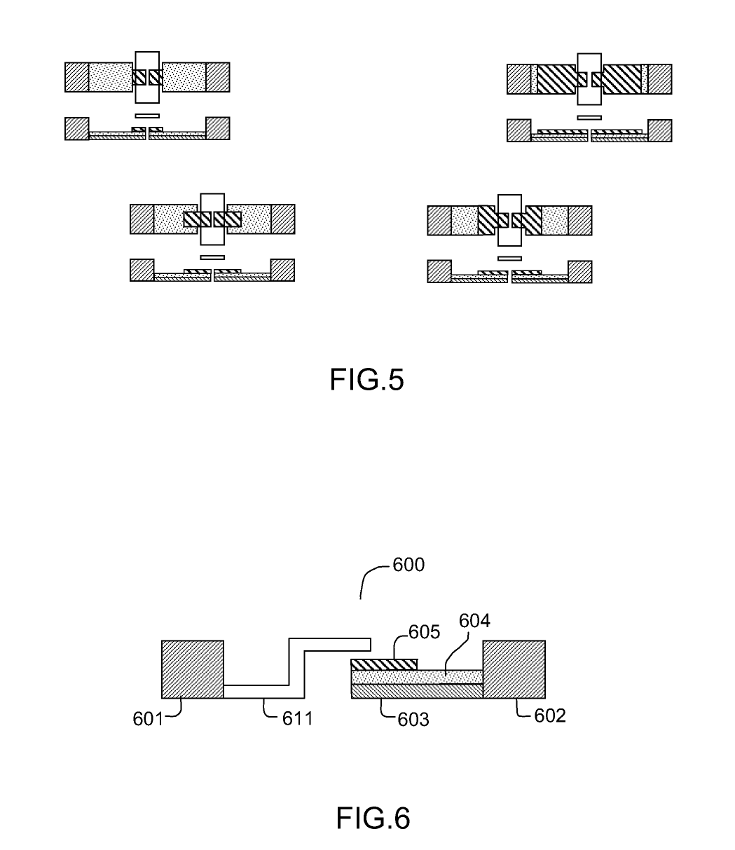

FIG. 5 has a top view and cross-sectional view of various examples of switched capacitor structures according to the invention.

By setting the values of the thicknesses of the various metal and dielectric layers, and by setting the area S of the second metal layer 405, it is possible to obtain different values of the capacitance C. It is well known to a person skilled in the art that the capacitance generated by a dielectric environment contained between two mutually confronting plane metallic surfaces, to the extent that the edge effects can be ignored, the area of the electrodes being very large in relation to the distance separating these electrodes, is given by the following relation:

$$C = \frac{{ɛ}_{0} {ɛ}_{r} A}{e} ,$$

∈₀ being the dielectric permittivity of the vacuum,
∈ᵣ being the relative permittivity of the dielectric,
A being the mutually confronting area of the electrodes,
E being the thickness of the dielectric separating the two electrodes.

It should be noted that the setting of these parameters does not influence the value of the equivalent capacitance of the structure according to the invention in the open state, the capacitance C_{O} being determined by the distance between the second metal layer 405 and the diaphragm 411 and by their mutually confronting area S₀; the area S of the second metal layer 405, then, may be selected sufficiently large so that S₀ is constant, whatever the area S.

The switched capacitor structure 400 according to the invention thus affords a reduced overall size in relation to the switched capacitor structures known from the prior art, the capacitor to be switched being integrated into the very structure of the MEMS switch controlling it.

Another advantage of the switched capacitor 400 according to the invention is that it can be produced on a single substrate by means of known lithographic techniques.

Finally, the service life of a switched capacitor 400 according to the invention is greater than the service life of a switched capacitor structure comprising an MEMS switch 201 in series with an MIM capacitor 203; to be precise, this last structure known from the prior art is subject to the relatively limited service life of the MEMS switch 201. In fact, it is known to a person skilled in the art that an MEMS switch 201 is subject to a sticking phenomenon, or charging phenomenon, after a certain number of operating cycles, this being linked to the accumulation of charges on the surface of the dielectric layer 304. The metal surface 405 of the structure of the invention, then, enables the charges to be released and thus greatly reduces the charging phenomenon by a factor of the order of 1/100 to 1/1000. The service life of a switched capacitor 400 according to the invention is therefore unaffected by the charging phenomenon.

It should be noted that all the exemplary embodiments of a switched capacitor 400 according to the invention are based on a series MEMS switch structure 201 of the “suspended diaphragm” type. Another series MEMS switch structure of the “cantilever” beam type may just as well serve as a structural basis for another exemplary embodiment of a switched capacitor.

FIG. 6 has a cross-sectional view of another exemplary embodiment of a switched capacitor 600 according to the invention. The switched capacitor 600 comprises an input line 601, an output line 602 and a first metal layer 603 covered by a dielectric layer 604; the dielectric layer is covered, on part of its surface, by a second metal layer 605. The first metal layer 603 is connected electrically to the output line 602. The input line 601 is connected to a metallic structure 611 comprising a movable beam of the cantilever beam type.

According to calculations similar to the calculations given above with reference to the preceding figures, the switched capacitor 600 has in the open state a capacitance approximately equal to C_{O}, that is to say the capacitance in the dielectric environment (typically air) contained between the mutually confronting surfaces of the movable beam 611 and of the second metal layer 605.

In the closed state, the capacitance of the switched capacitor 600 is equal to C, C being the capacitance in the dielectric between the second metal layer 605 and the first metal layer 603.

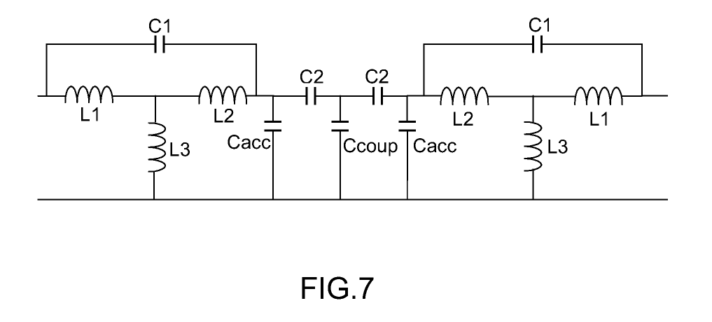

FIG. 7 has the electrical diagram of an example of a frequency-tunable filter with a constant passband 700 employing switched capacitors according to the invention.

The frequency-tunable filter 700 comprises a first oscillating circuit 701 and a second oscillating circuit 702, each being tuned by means of a tuning capacitor of capacitance C_{acc} and C′_{acc} respectively. The two oscillating circuits 701 and 702 are coupled by means of a coupling device 703.

The first oscillating circuit 701 comprises, for example, a T-connection of three coils L₁, L₂ and L₃, L₃ being connected to a reference potential, for example an earth potential, and between the coils L₁ and L₂. A capacitor of fixed capacitance C₁ is connected in parallel to the coils L₁ and L₂. The tuning capacitor C_{acc} is connected between the output of the coil L₂ and earth.

The second oscillating circuit 702 has a structure identical to that of the first oscillating circuit 701, the tuning capacitor C_{acc} being connected upstream of the circuit comprising the coils L₁, L₂, L₃ and the capacitor C₁.

The coupling device 703 is, for example, a T-connection of capacitors, where the arm connected to earth comprises a capacitor of capacitance C_{coup} connected, furthermore, to a point between two capacitors of fixed capacitance C₂.

The capacitances C_{acc}, C′_{acc} and C_{coup} may be variable capacitances obtained by means of a connection of a plurality of switched capacitors 400 or 600 according to the present invention. The capacitances C_{acc} and C_{coup} assume, for example, at least 6 values. The frequency-tunable filter 700 may, for example, operate in the band 400-600 MHz and allow a frequency step of 12 MHz.

What is claimed is:

1- A switched capacitor, comprising a series MEMS-type switch, the MEMS switch comprising a first metal layer, a dielectric material layer and an actuatable metallic diaphragm having a high state and a low state, the second metal layer being formed on part of the surface of the dielectric material layer, a line disconnection formed by an absence of metal being implemented on at least the first metal layer and the second metal layer, below the actuatable metallic diaphragm, the capacitor to be switched being formed by the dielectric material layer contained between the mutually confronting surfaces of the first metal layer and of the second metal layer, the diaphragm in the low state being in direct contact with the second metal layer.

2- A switched capacitor according to claim 1, wherein the series MEMS switch is of the type of switch with a suspended diaphragm, the diaphragm being located above the line disconnection made at mid-length over the entire width and entire thickness of at least the first metal layer and the second metal layer, the diaphragm in the low state making ohmic contact between the parts of the second metal layer which are located on either side of the line disconnection.

3- A switched capacitor according to claim 1, wherein the series MEMS switch is of the type of switch with a cantilever beam, comprising a movable beam having a high state and a low state, the movable beam being located above the second metal layer, the movable beam in the low state making ohmic contact with the second metal layer.

4- A switched capacitor according to claim 1, wherein the capacitance value is set as a function of the area of the second metal layer.

5- Use of a plurality of switched capacitors according to claim 1 in a device with switched capacitors.

6- Use of a plurality of switched capacitors according to claim 1 in a variable-capacitance device, the switched capacitors having capacitances of specific values and being connected in parallel.

7- A frequency-tunable filter comprising a first oscillating circuit, a second oscillating circuit and a coupling device, wherein the first oscillating circuit and the second oscillating circuit are tuned respectively by means of two tuning capacitors of variable capacitance, the coupling device being a T-connection of three capacitors, comprising two capacitors of fixed capacitance on the two transverse arms of the T-connection and one variable-capacitance capacitor on the earthed arm of the T-connection, the variable-capacitance capacitors being variable-capacitance devices according to claim 6.

8- A frequency-tunable filter according to claim 7, wherein the first and second oscillating circuits comprise a T-connection comprising a first coil, a second coil and a third coil, the first and second coils being respectively on the two transverse arms of the T-connection, the third coil being on the earthed arm of the T-connection, a fixed-capacitance capacitor being connected in parallel to the first and second coils.
